(19) United States
(12) Patent Application Publication
(10) Pub. No.: US 2022/0025510 A1
(43) Pub. Date: Jan. 27, 2022

(54) TUNGSTEN OXIDE SPUTTERING TARGET

(71) Applicant: MITSUBISHI MATERIALS CORPORATION, Tokyo (JP)

(72) Inventors: Go Yamaguchi, Yoshinogawa-shi (JP); Kensuke Io, Sanda-shi (JP); Shiori Kawamura, Koube-shi (JP); Keita Umemoto, Sanda-shi (JP)

(73) Assignee: MITSUBISHI MATERIALS CORPORATION, Tokyo (JP)

(21) Appl. No.: 17/312,087

(22) PCT Filed: Mar. 12, 2020
(86) PCT No.: PCT/JP2020/010729

§ 371 Date: Jun. 9, 2021

(30) Foreign Application Priority Data
Mar. 15, 2019 (JP) 2019-048885
Mar. 6, 2020 (JP) 2020-039257

(51) Int. Cl. C23C 14/34; C23C 14/08; C01G 41/02

(52) U.S. Cl. CPC C23C 14/3407; C23C 14/083; C01P 2002/72; C01P 2002/74; C01P 2002/52; C01G 41/02

(57) ABSTRACT

A W₁₈O₄₉ peak is confirmed by X-ray diffraction analysis of a sputtering surface and a cross section orthogonal to the sputtering surface, a ratio I_{S(103)}/I_{S(010)} of a diffraction intensity I_{S(103)} of a (103) plane to a diffraction intensity I_{S(010)} of a (010) plane of W₁₈O₄₉ of the sputtering surface is 0.57 or more, a ratio I_{C(103)}/I_{C(010)} of a diffraction intensity I_{C(103)} of the (103) plane to a diffraction intensity I_{C(010)} of the (010) plane of W₁₈O₄₉ of the cross section is 0.38 or less, and an area ratio of the W₁₈O₄₉ phase of a surface parallel to the sputtering surface is 37% or more.

### TECHNICAL FIELD

The present invention relates to a tungsten oxide sputtering target used when forming a tungsten oxide film.

Priority is claimed on Japanese Patent Application Nos. 2019-048885 and 2020-039257, filed Mar. 15, 2019 and Mar. 6, 2020, the contents of which are incorporated herein by reference.

### BACKGROUND ART

The tungsten oxide film is used in various fields such as an electrochromic display element and a light-shielding member. In addition, Patent Document 1 discloses that a tungsten oxide film (WO_{X} film) is used as a positive electrode of an organic EL element.

As described in Patent Document 1, the tungsten oxide film described above is formed by a sputtering method using a sputtering target.

As a sputtering target for forming a tungsten oxide film, for example, as shown in Patent Documents 2 and 3, a tungsten oxide sputtering target formed of a sintered body obtained by sintering a tungsten oxide powder is provided.

Patent Document 2 discloses a tungsten oxide sputtering target to which manganese or a manganese compound is added as a sintering aid in order to improve a density of the sintered body.

In addition, Patent Document 3 discloses a tungsten oxide sputtering target formed of a sintered body sintered in a vacuum by using a tungsten oxide powder containing WO₂ and at least one of W₁₈O₄₉ and WO₃, the sintered body having a composition formed of two or more phases of a WO₂ phase and a W₁₈O₄₉ phase, in order to enable DC sputtering.

### CITATION LIST

### Patent Documents

[Patent Document 1]

Japanese Unexamined Patent Application, First Publication No. H11-067459

[Patent Document 2]

Japanese Unexamined Patent Application, First Publication No. H10-259054

[Patent Document 3]

Japanese Unexamined Patent Application, First Publication No. 2013-076163

### SUMMARY OF INVENTION

### Technical Problem

Recently, in order to efficiently form a tungsten oxide film, a power higher than that of the related art may be applied to a tungsten oxide sputtering target to form a sputtering film.

In the tungsten oxide sputtering target formed of a sintered body, cracks may occur on a sputtering surface, in a case where the sputtering is performed under high power conditions. In addition, although the cracks do not occur at an initial stage of sputtering, in a case where the sputtering proceeds and a depth of an erosion portion becomes deeper, the cracks tend to easily occur when a high power is applied.

The present invention has been made in view of the above-mentioned circumstances, and an object thereof is to provide a tungsten oxide sputtering target capable of suppressing occurrence of cracks and stably performing sputtering film formation for a long period of time, although the sputtering is performed under high power conditions.

### Solution to Problem

As a result of intensive studies by the present inventors in order to solve the above problems, the following findings were obtained.

By setting crystal orientation on a sputtering surface and crystal orientation on a cross section orthogonal to the sputtering surface in a predetermined range, it is possible to suppress the occurrence of cracks even when a high power is applied, and it is possible to suppress the occurrence of cracks, even when the sputtering has proceeded. The improvement in hardness of the sputtering surface, by setting the crystal orientation on the sputtering surface and the crystal orientation on the cross section orthogonal to the sputtering surface in the predetermined range, is considered as one reason thereof.

The present invention has been made based on the above findings, and there is provided a tungsten oxide sputtering target of the present invention, in which a W₁₈O₄₉ peak is confirmed by X-ray diffraction analysis of a sputtering surface and a cross section orthogonal to the sputtering surface, a ratio I_{S(103)}/I_{S(010)} of a diffraction intensity I_{S(103)} of a (103) plane to a diffraction intensity I_{S(103)} of a (010) plane of W₁₈O₄₉ of the sputtering surface is 0.57 or more, a ratio I_{C(103)}/I_{C(010)} of a diffraction intensity I_{C(103)} of the (103) plane to a diffraction intensity I_{C(010)} of the (010) plane of W₁₈O₄₉ of the cross section is 0.38 or less, and an area ratio of the W₁₈O₄₉ phase of a surface parallel to the sputtering surface is 37% or more.

According to the tungsten oxide sputtering target having this configuration, the W₁₈O₄₉ peak is confirmed by the X-ray diffraction analysis on the sputtering surface and the cross section orthogonal to the sputtering surface, and the area ratio of the W₁₈O₄₉ phase of the surface parallel to the sputtering surface is 37% or more. Accordingly, it is possible to ensure conductivity and stably perform DC sputtering. In addition, it is possible to ensure the hardness of the tungsten oxide sputtering target.

The ratio I_{S(103)}/I_{S(010)} of the diffraction intensity I_{S(103)} of the (103) plane to the diffraction intensity I_{S(010)} of the (010) plane of W₁₈O₄₉ of the sputtering surface is 0.57 or more, the ratio I_{C(103)}/I_{C(010)} of the diffraction intensity I_{C(103)} of the (103) plane to the diffraction intensity I_{C(010)} of the (010) plane of W₁₈O₄₉ of the cross section orthogonal to the sputtering surface is 0.38 or less, and the (103) plane of W₁₈O₄₉ is strongly oriented on the sputtering surface. Accordingly, it is possible to suppress the occurrence of cracks, although the high power is applied. In addition, even when the sputtering proceeds and the erosion portion is formed, the crystal orientation on the sputtering surface is maintained, and the occurrence of cracks can be suppressed, even when a high power is applied.

The tungsten oxide sputtering target of the present invention preferably has a composition of WO_{X} (2.1≤X≤2.9).

In this case, since the composition is WO_{X} (2.1≤X≤2.9), the presence of a large amount of WO₂ and WO₃ phases is suppressed, and it is possible to sufficiently ensure the W₁₈O₄₉ phase having high conductivity and more stably perform the DC sputtering. In addition, it is possible to sufficiently ensure the hardness of the tungsten oxide sputtering target.

In addition, it is preferable that, the tungsten oxide sputtering target of the present invention contains an oxide of any one or two or more additive metals of Nb, Ta, Ti, Zr, Y, Al and Si, and as a metal component, in a case where a total amount of the additive metal is defined as M (mass %) and an amount of tungsten is defined as W (mass %), M/(W+M) is in a range of 0.1 or more and 0.67 or less.

In this case, the oxide of any one or two or more additive metals of Nb, Ta, Ti, Zr, Y, Al and Si is contained, and in a case where a total amount of the additive metal is defined as M (atom %) and an amount of tungsten is defined as W (atom %), M/(W+M) is 0.1 or more. Accordingly, it is possible to improve alkali resistance of the formed oxide film. In addition, since M/(W+M) is 0.67 or less, it is possible to suppress the occurrence of abnormal discharge due to the oxide of the additive metal.

### Advantageous Effects of Invention

According to the present invention, it is possible to provide a tungsten oxide sputtering target capable of suppressing occurrence of cracks and stably performing sputtering film formation for a long period of time, although the sputtering is performed under high power conditions.

### BRIEF DESCRIPTION OF DRAWINGS

FIG. 1 is a diagram showing an X-ray diffraction analysis result of a sputtering surface of a tungsten oxide sputtering target and a cross section orthogonal to the sputtering surface according to an embodiment of the present invention.

FIG. 2 is a flowchart showing a method for manufacturing the tungsten oxide sputtering target according to an embodiment of the present invention.

### DESCRIPTION OF EMBODIMENTS

Hereinafter, the tungsten oxide sputtering target according to the embodiment of the present invention will be described with reference to the accompanying drawings.

In the tungsten oxide sputtering target according to the present embodiment, the W₁₈O₄₉ peak is confirmed by the X-ray diffraction analysis on the sputtering surface and the cross section orthogonal to the sputtering surface, and the area ratio of the W₁₈O₄₉ phase of the surface parallel to the sputtering surface is 37% or more.

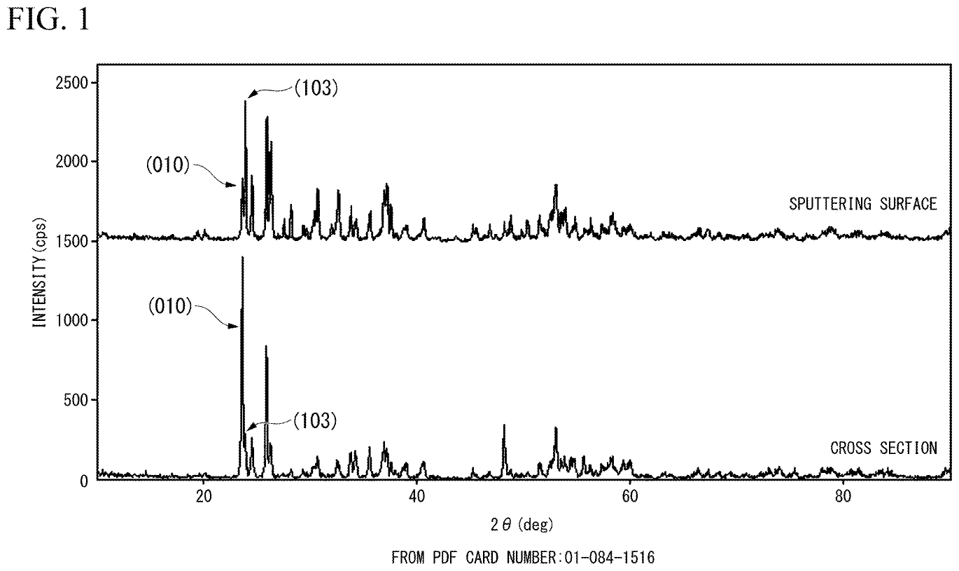

In the tungsten oxide sputtering target according to the present embodiment, as shown in FIG. 1, as a result of the X-ray diffraction measurement, the ratio I_{S(103)}/I_{S(010)} of the diffraction intensity I_{S(103)} of the (103) plane to the diffraction intensity I_{S(010)} of the (010) plane of W₁₈O₄₉ of the sputtering surface is 0.57 or more.

In addition, the ratio I_{C(103)}/I_{C(010)} of the diffraction intensity I_{C(103)} of the (103) plane to the diffraction intensity I_{C(010)} of the (010) plane of W₁₈O₄₉ of the cross section orthogonal to the sputtering surface is 0.38 or less.

The tungsten oxide sputtering target of the present embodiment preferably has a composition of WO_{X} (2.1≤X≤2.9).

It is preferable that, the tungsten oxide sputtering target of the present embodiment contains an oxide of any one or two or more additive metals of Nb, Ta, Ti, Zr, Y, Al and Si, and as a metal component, in a case where a total amount of the additive metal is defined as M (atom %) and an amount of tungsten is defined as W (atom %), M/(W+M) is in a range of 0.1 or more and 0.67 or less.

In the tungsten oxide sputtering target according to the present embodiment, regarding the ratio I_{S(103)}/I_{S(010)} of the diffraction intensity I_{S(103)} of the (103) plane to the diffraction intensity I_{S(010)} of the (010) plane of W₁₈O₄₉ of the sputtering surface, the ratio I_{C(103)}/I_{C(010)} of the diffraction intensity I_{C(103)} of the (103) plane to the diffraction intensity I_{C(010)} of the (010) plane of W₁₈O₄₉ of the cross section orthogonal to the sputtering surface, the area ratio of the W₁₈O₄₉ phase of the surface parallel to the sputtering surface, and the composition, the reasons for defining as described above will be described.

(Diffraction Intensity Ratio I_{S(103)}/I_{S(010)} of Sputtering Surface)

Since the (103) plane of W₁₈O₄₉ is harder than the planes of other orientations, it is possible to suppress the occurrence of cracks by controlling the crystal orientation so that the (103) plane is strongly oriented on the sputtering surface.

Therefore, in the present embodiment, the ratio I_{S(103)}/I_{S(010)} of the diffraction intensity I_{S(103)} of the (103) plane to the diffraction intensity I_{S(010)} of the (010) plane of W₁₈O₄₉ of the sputtering surface is set as 0.57 or more.

The ratio I_{S(103)}/I_{S(010)} of the diffraction intensity I_{S(103)} of the (103) plane to the diffraction intensity I_{S(010)} of the (010) plane of W₁₈O₄₉ of the sputtering surface is preferably 1.2 or more and more preferably 2.02 or more. In addition, an upper limit of I_{S(103)}/I_{S(010)} is not particularly limited, and is preferably 2.56 or less.

(Diffraction Intensity Ratio I_{C(103)}/I_{C(010)} of cross section orthogonal to sputtering surface)

As the sputtering proceeds, an erosion portion is formed on the sputtering surface. In a case where the orientation of the (103) plane of W₁₈O₄₉ is low on the cross section orthogonal to the sputtering surface, although the sputtering has proceeded, a state in which the (103) plane is strongly oriented on the sputtering surface is maintained. Accordingly, it is possible to suppress the occurrence of cracks even after the sputtering has proceeded.

Therefore, in the present embodiment, the ratio I_{C(103)}/I_{C(010)} of the diffraction intensity I_{C(103)} of the (103) plane to the diffraction intensity I_{C(010)} of the (010) plane of W₁₈O₄₉ of the cross section orthogonal to the sputtering surface is set as 0.38 or less.

The ratio I_{C(103)}/I_{C(010)} of the diffraction intensity I_{C(103)} of the (103) plane to the diffraction intensity I_{C(010)} of the (010) plane of W₁₈O₄₉ of the cross section orthogonal to the sputtering surface is preferably 0.30 or less and more preferably 0.18 or less. In addition, a lower limit of I_{C(103)}/I_{C(010)} is not particularly limited, and is preferably 0.13 or more.

(Area Ratio of W₁₈O₄₉ Phase on Surface Parallel to Sputtering Surface)

Since the W₁₈O₄₉ phase of tungsten oxide has high conductivity, it is possible to improve the conductivity by ensuring the area ratio of the W₁₈O₄₉ phase and to form a tungsten oxide film stably by the DC sputtering.

Therefore, in the present embodiment, the area ratio of the W₁₈O₄₉ phase on the surface parallel to the sputtering surface is set to 37% or more. The area ratio of the W₁₈O₄₉ phase on the surface parallel to the sputtering surface can be calculated from an image obtained by performing EPMA analysis on an observation surface of an observation sample. Even in a case where oxides of these additive metals of any one or two or more of Nb, Ta, Ti, Zr, Y, Al, and Si are contained in addition to tungsten oxide, the area ratio of the W₁₈O₄₉ phase may be 37% or more with respect to the entire surface parallel to the sputtering surface containing the oxides of these additive elements.

The area ratio of the W₁₈O₄₉ phase on the surface parallel to the sputtering surface is preferably 55% or more and more preferably 85% or more. In addition, an upper limit of the area ratio of the W₁₈O₄₉ phase on the surface parallel to the sputtering surface is not particularly limited, and is preferably 94% or less.

### (Composition)

Since various phases such as a WO₂ phase, a WO₃ phase, and a W₁₈O₄₉ phase are mixed in tungsten oxide, a ratio of tungsten and oxygen is defined as WO_{X}.

By setting X to 2.1 or more, the ratio of the WO₂ phase can be suppressed, and the W₁₈O₄₉ phase having excellent conductivity can be sufficiently ensured. By setting X to 2.9 or less, the ratio of the WO₃ phase can be suppressed, and the W₁₈O₄₉ phase having excellent conductivity can be sufficiently ensured. That is, by setting X to 2.1 or more and 2.9 or less, the W₁₈O₄₉ phase becomes a main phase (matrix), and the conductivity of the sputtering target can be ensured.

A lower limit of X is preferably 2.4 or more. In addition, an upper limit of X is preferably 2.82 or less.

### (Oxide of Additive Metal)

In the formed oxide film, alkali is used as a resist peeling solution during patterning by an etching method. By containing the oxide of additive metal of any one or two or more of Nb, Ta, Ti, Zr, Y, Al, and Si in tungsten oxide, it is possible to improve the alkali resistance of tungsten oxide. Meanwhile, in a case where an amount of the oxide of the additive metal is extremely great, an abnormal discharge may occur during sputtering due to the oxide of the additive metal.

Therefore, in the present embodiment, in a case where an oxide of any one or two or more additive metals of Nb, Ta, Ti, Zr, Y, Al and Si is contained, in a case where a total amount of the additive metal is defined as M (atom %) and an amount of tungsten is defined as W (atom %) as the metal component, M/(W+M) is regulated in a range of 0.1 or more and 0.67 or less.

A lower limit of M/(W+M) is preferably 0.15 or more and more preferably 0.2 or more. On the other hand, an upper limit of M/(W+M) is preferably 0.5 or less and more preferably 0.4 or less.

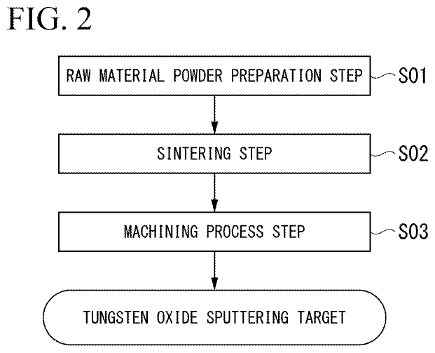

Next, a method for manufacturing the tungsten oxide sputtering target according to the present embodiment will be described with reference to FIG. 2.

As shown in FIG. 2, the method for manufacturing the tungsten oxide sputtering target according to the present embodiment includes a raw material powder preparation step S01, a sintering step S02 for sintering the raw material powder, and a machining process step S03 of machining the obtained sintered body.

(Raw Material Powder Preparation Step S01) By reducing the WO₃ powder, a WO_{X} powder containing the WO₂ powder and the W₁₈O₄₉ powder is obtained. This WO_{X} powder may contain a WO₃ powder. A purity of WO_{X} powder is 99.9 mass % or more. The X of the WO_{X} powder is controlled by adjusting the conditions of the reduction treatment.

As the reduction treatment, for example, the WO₃ powder is heated in a hydrogen atmosphere for a predetermined time at a predetermined temperature to reduce hydrogen. In this hydrogen reduction, the reduction proceeds in the order of WO₃ to WO_{02.9}, WO_{2.72}, WO₂, and W. By controlling the proceeding situation of the reduction, it is possible to prepare powders in a mixed state having the composition having different reduction states, and to finely fluctuate an X value of the WO_{X} powder.

In addition, as a method for controlling and finely adjusting the X value of the WO_{X} powder, a powder formed of WO₃, WO_{2.9}, WO_{2.72}, WO₂, and W can be appropriately mixed with the powder subjected to the reduction treatment as described above.

In the quantitation of the X in WO_{X}, the sampled WO_{X} is weighed, then heat-treated at 800° C. for 1 hour in the atmosphere, and the weight is measured after the heat treatment. Then, it is confirmed that all of them are WO₃ by X-ray diffraction analysis, and a W amount is calculated by the following formula. Then, a ratio of oxygen is calculated as the X from the obtained W amount.

Weight of W=Weight after heat treatment×M_{W}/M_{WO3}

W (mass %)=(weight of W/weight of WO_{X} before heat treatment)×100

M_{W}: Atomic weight of W (183.85), M_{WO3}: Atomic weight of WO₃ (231.85)

The raw material powder is obtained by mixing the obtained WO_{X} powder. As a mixing method, for example, a dry ball mill using zirconia balls can be used. The mixing method is not limited, and a mixer or a blender, specifically, Henschel, rocking, a recon, or the like can be applied.

An average particle diameter of the raw material powder is preferably in a range of 1 μm or more and 30 μm or less.

In a case where the oxide of additive metals of any one or two or more of Nb, Ta, Ti, Zr, Y, Al, and Si is added, various oxide powders are mixed with the WO_{X} powder described above. As a mixing method, for example, a dry ball mill using zirconia balls can be used. The mixing method is not limited, and a mixer or a blender, specifically, Henschel, rocking, a recon, or the like can be applied.

In addition, the oxide powder of the additive metal preferably has a greater particle diameter than that of the WO_{X} powder so as not to disturb the sintering of the WO_{X} powders.

### (Sintering Step S02)

Next, the raw material powder described above is sintered by pressurizing and heating to obtain a sintered body. In the present embodiment, the sintering was performed in vacuum using a hot press device.

A sintering temperature in the sintering step S02 is in a range of 850° C. or higher and 1,400° C. or lower, a holding time at the sintering temperature is in a range of 1 hour or longer and 4 hours or shorter, and a pressurizing pressure is in a range of 10 MPa or more and 35 MPa or less.

In the present embodiment, the crystal orientation of the sintered body is controlled by controlling the temperature as follows in the sintering step S02.

First, before starting the temperature rise, the pressurization is performed at the pressurizing pressure described above, and the temperature is raised at a temperature rise rate in a range of 5° C./min or more and 20° C./min or less. Then, it is held at an intermediate temperature in a range of 586° C. or higher and 750° C. or less in a range of 1 hour or longer and 2 hours or shorter. After that, the sintering is performed by raising the temperature to the sintering temperature described above and holding the temperature.

Accordingly, the (103) plane of W₁₈O₄₉ is strongly oriented on a pressurizing surface (surface orthogonal to a pressurizing direction), and the (010) plane of W₁₈O₄₉ is strongly oriented on a surface orthogonal to the pressurizing surface (surface along the pressurizing direction).

A lower limit of the intermediate temperature described above is preferably 600° C. or higher, and an upper limit of the intermediate temperature is preferably 700° C. or lower.

### (Machining Process Step S03)

Next, the obtained sintered body is machined to have a predetermined dimension. At this time, the machining is performed so that the pressurizing surface is a sputtering surface.

Accordingly, the tungsten oxide sputtering target of the present embodiment is manufactured.

According to the tungsten oxide sputtering target of the present embodiment having the configuration described above, the W₁₈O₄₉ peak is confirmed by the X-ray diffraction analysis on the sputtering surface and the cross section orthogonal to the sputtering surface, and the area ratio of W₁₈O₄₉ phase of the surface parallel to the sputtering surface is 37% or more. Accordingly, it is possible to ensure conductivity and stably perform DC sputtering. In addition, it is possible to ensure the hardness of the tungsten oxide sputtering target.

In the tungsten oxide sputtering target of the present embodiment, the ratio I_{S(103)}/I_{S(010)} of the diffraction intensity I_{S(103)} of the (103) plane to the diffraction intensity I_{S(010)} of the (010) plane of W₁₈O₄₉ of the sputtering surface is 0.57 or more, the ratio I_{C(103)}/I_{C(010)} of the diffraction intensity I_{C(103)} of the (103) plane to the diffraction intensity I_{C(010)} of the (010) plane of W₁₈O₄₉ of the cross section orthogonal to the sputtering surface is 0.38 or less, and the (103) plane of W₁₈O₄₉ is strongly oriented on the sputtering surface. Accordingly, it is possible to suppress the occurrence of cracks, although the high power is applied. In addition, even when the sputtering proceeds and the erosion portion is formed, the crystal orientation on the sputtering surface is maintained, and the occurrence of cracks can be suppressed, even when a high power is applied.

Further, in the tungsten oxide sputtering target of the present embodiment, in a case where the composition is WO_{X} (2.1≤X≤2.9), the presence of a large amount of WO₂ phase or WO₃ phase is suppressed, and it is possible to sufficiently ensure the W₁₈O₄₉ phase and more stably perform the DC sputtering. In addition, it is possible to sufficiently ensure the hardness of the tungsten oxide sputtering target.

In addition, the tungsten oxide sputtering target of the present embodiment contains an oxide of any one or two or more additive metals of Nb, Ta, Ti, Zr, Y, Al and Si, and in a case where a total amount of the additive metal is defined as M (atom %) and an amount of tungsten is defined as W (atom %), M/(W+M) is in a range of 0.1 or less 0.67 and less. In this case, it is possible to improve the alkali resistance of the formed oxide film and suppress the occurrence of abnormal discharge due to the oxide of the additive metal.

The embodiments of the present invention have been described as above, but the present invention is not limited thereto, and can be appropriately changed without departing from the technical ideas of the present invention.

### Examples

Hereinafter, a result of an evaluation test for evaluating an action effect of the tungsten oxide sputtering target according to the present invention will be described.

First, the WO_{X} powder was produced by hydrogen-reduction treatment of the WO₃ powder described above. In this example, the WO_{X} powders having different x values were prepared by adjusting a degree of reduction. An average particle diameter of the raw material powder was 2.4 μm.

In addition, as the oxide powders of various additive metals, a Nb₂O₅ powder (purity: 99.9 mass %, particle diameter D50: 4.6 μm), a Ta₂O₅ powder (purity: 99.9 mass %, particle diameter D50: 3.5 μm), a TiO₂ powder (purity: 99.9 mass %, particle diameter D50: 2.6 μm), a ZrO₂ powder (purity: 99.9 mass %, particle diameter D50: 11 μm), a Y₂O₃ powder (purity: 99. 9 mass %, particle diameter D50: 2.3 μm), an Al₂O₃ powder (purity: 99.9 mass %, particle diameter D50: 0.2 μm), and a SiO₂ powder (purity: 99.9 mass %, particle diameter D50: 1.9 μm) were prepared and mixed with the WO_{X} powder in the formulations shown in Tables 1 and 2.

Using this raw material powder, a sintering step was carried out with an apparatus (method) and under conditions shown in Tables 1 and 2, to obtain a sintered body. In Tables 1 and 2, “HP” indicates hot pressing in a vacuum atmosphere, “HIP” indicates a hot isostatic pressing method, and “atmospheric firing” indicates uniaxial molding in an atmospheric atmosphere.

In “HP”, the sintering was carried out under the sintering conditions A to D shown below.

Under the sintering condition A, the temperature was raised at a temperature rise rate of 10° C./min while pressurizing under the pressurizing pressures shown in Tables 1 and 2, and the temperature was held at 600° C. (intermediate temperature) for 1 hour. Then, the temperature was raised to the sintering temperature shown in Tables 1 and 2 at a temperature rise rate of 10° C./min, and the temperature was held at the sintering temperature for 2 hours. After that, the pressure was released and the mixture was allowed to cool.

Under the sintering condition B, the temperature was raised at a temperature rise rate of 10° C./min while pressurizing under the pressurizing pressures shown in Tables 1 and 2, and the temperature was held at 700° C. (intermediate temperature) for 1 hour. Then, the temperature was raised to the sintering temperature shown in Tables 1 and 2 at a temperature rise rate of 10° C./min, and the temperature was held at the sintering temperature for 2 hours. After that, the pressure was released and the mixture was allowed to cool.

Under the sintering condition C, the temperature was raised to the sintering temperature without holding at the intermediate temperature, and the temperature was held at the sintering temperature for 2 hours. After that, the pressure was released and the mixture was allowed to cool.

Under the sintering condition D, the temperature was raised at a temperature rise rate of 10° C./min while pressurizing under the pressurizing pressures shown in Tables 1 and 2, and the temperature was held at 800° C. for 1 hour. Then, the temperature was raised to the sintering temperature shown in Tables 1 and 2 at a temperature rise rate of 10° C./min, and the temperature was held at the sintering temperature for 2 hours. After that, the pressure was released and the mixture was allowed to cool.

In “HIP”, a metal can filled with the raw material powder in a vacuum-sealed state was placed in a pressure vessel of a hot isostatic pressing device that carries out a hot isostatic pressing method, and it is held at the pressure, the sintering temperature shown in FIGS. 1 and 2 for 2 hours, and the sintering was performed.

In the “atmospheric firing”, a die was filled with raw material powder and compression molded by uniaxial molding to obtain a molded body. This molded body was charged into an atmosphere furnace and held at the sintering temperatures shown in Tables 1 and 2 for 20 hours to perform the sintering.

Then, the obtained sintered body was machined to produce a disc-shaped tungsten oxide sputtering target having a diameter of 152.4 mm and a thickness of 6 mm. In the sintered body manufactured by the “HP”, the machining was performed so that the pressurizing surface became a sputtering surface.

The obtained tungsten oxide sputtering target was evaluated for the following items.

### (Composition of Tungsten Oxide Sputtering Target)

A measurement sample was collected from the obtained tungsten oxide sputtering target, this measurement sample was pulverized in a mortar, and X was confirmed by the method for quantifying X of the WO_{X} described above. As a result, it was confirmed that there was no change in X from the blended WO_{X} powder. The evaluation results are shown in Tables 1 and 2.

Regarding the measurement of the degree of oxidation of Examples 13 to 20 of the present invention to which the oxide of the additive metal is added, first, an observation sample was collected from the obtained tungsten oxide sputtering target, this was embedded in an epoxy resin so that the cross section parallel to the sputtering surface is an observation surface, a polishing treatment was performed, and then, an element distribution image showing composition distribution of the elements was observed by using a field emission type electron probe microanalyzer (EPMA). In addition, in the observation with EPMA, an image of an observation field of view of 0.005 mm² (magnification: 500 times) was captured. In any five points of a region of the obtained element mapping image of W where W is detected, the quantitative analysis using standard samples of W and O was performed, and an average value of values obtained by measuring the degree of oxidation of W was shown in a column of WOx value of Tables 1 and 2.

In addition, in Examples 13 to 21 of the present invention in which the oxide of the additive metal was added, fragments of the obtained tungsten oxide sputtering target to which the oxide of the additive metal was added were ground in a Menou mortar, and the powder was dissolved with acid or alkali. After that, the amount of the additive metal was measured by an ICP emission analyzer.

### (X-Ray Diffraction Analysis of Sputtering Surface and Cross Section Orthogonal to Sputtering Surface)

From the obtained tungsten oxide sputtering target, a measurement sample was collected so that the sputtering surface and the cross section orthogonal to the sputtering surface are measurement surfaces, and the measurement surfaces were wet-polished with SiC-Paper (grit 180).

The X-ray diffraction analysis was performed under the following conditions by using RINT-ULtima/PC manufactured by Rigaku Denki Co., Ltd.
Tube: Cu
Tube voltage: 40 kV
Tube current: 50 mA
Scanning range (2θ): 5° to 80°
Slit size: divergence (DS) ⅔ degree, scattering (SS) ⅔ degree, light receiving (RS) 0.8 mm
Measurement step width: 0.02 degrees at 2θ
Scan speed: 2 degrees per minute
Sample table rotation speed: 30 rpm

A surface index of the obtained X-ray diffraction peak was confirmed using a PDF card number: 1-084-1516 (W₁₈O₄₉).

The ratio I_{S(103)}/I_{S(010)} of the diffraction intensity I_{S(103)} of the (103) of the (103) plane to the diffraction intensity I_{S(010)} of the (010) plane of W₁₈O₄₉ of the sputtering surface and the ratio I_{C(103)}/I_{C(010)} of the diffraction intensity I_{C(103)} of the (103) plane to the diffraction intensity I_{C(010)} of the (010) plane of W₁₈O₄₉ of the cross section orthogonal to the sputtering surface were calculated. The evaluation results are shown in Tables 3 and 4.

### (Density)

A density at room temperature was measured from the dimension and weight of the measurement sample. The measurement results are shown in Tables 3 and 4.

(Area Ratio of W₁₈O₄₉ Phase)

First, an observation sample was collected from the obtained tungsten oxide sputtering target, this was embedded in an epoxy resin so that the cross section parallel to the sputtering surface is an observation surface, a polishing treatment was performed, and then, an element distribution image showing composition distribution of the elements was observed by using a field emission type electron probe microanalyzer (EPMA). In addition, in the observation with EPMA, five images of an observation field of view of 0.005 mm² (magnification: 500 times) were captured, and the area of the W₁₈O₄₉ phase observed in the images was measured. The measurement results are shown in Tables 3 and 4.

The area ratio of the W₁₈O₄₉ phase can be measured by the following procedures (a) to (e).
(a) The generated phase on the observation surface of the observation sample is confirmed by X-ray diffraction analysis under the conditions described above.
(b) The phase analyzed as W₁₈O₄₉ phase in (a) is identified in the observation field of view by element analysis of EPMA.
(c) Five images of the observation field of view of COMPO image (60 μm×80 μm) having a magnification of 500 times were captured by EPMA.
(d) The W₁₈O₄₉ phase identified in (b) is extracted by commercially available image analysis software, and the captured image is converted into a monochrome image and binarized. As the image analysis software, for example, WinRoof Ver. 5.6.2 (manufactured by Mitani Corporation) and the like can be used.
(e) From all the binarized images, a total area of all W₁₈O₄₉ phase is calculated and divided by the area of all binarized regions, and the area ratio of the W₁₈O₄₉ phase with respect to the entire observation region is calculated.

### (Hardness of Sputtering Surface)

An observation sample was collected from the obtained tungsten oxide sputtering target, and a hardness of the sputtering surface was measured.

The hardness was measured using a Vickers hardness tester under the conditions of a load of 500 gf and a time of 10 seconds. The measurement results are shown in Tables 3 and 4.

### (Occurrence State of Cracks in Sputtering Test)

A sputtering test was performed using a DC magnetron sputtering apparatus under the conditions of ultimate vacuum degree of 5×10⁻⁵ Pa or less and sputtering Ar gas pressure of 0.3 Pa.

At this time, the sputtering output was increased by 100 W every 10 minutes from DC 100 W, and the sputtering output in which cracks occurred was confirmed. The evaluation results are shown in Tables 3 and 4.

In Tables 3 and 4, “initial stage” is a result of a sputtering test after performing the pre-sputtering for 1 hour. A “middle stage” is a result of a sputtering test in a state where a depth of the erosion portion reaches ½ of a target thickness.

### (Alkali Resistance)

Using the DC magnetron sputtering device, a 100 nm film was formed on a glass substrate under the conditions of ultimate vacuum degree of 5×10⁻⁵ Pa or less, a sputtering Ar gas pressure of 0.3 Pa, a sputtering output of 300 W, Ar gas of 90 sccm, and oxygen gas of 10 sccm. The obtained film was immersed in a 2.38 mass % aqueous solution of tetramethylammonium hydroxide (TMAH), and the time until the film disappeared was measured and shown in Table 3. In a case where it was 60 seconds or longer, it was determined that the product has alkali resistance that can withstand the wiring step (development of the photoresist step).

TABLE 1

| | | Raw | | | | | | | | |
|---|---|---|---|---|---|---|---|---|---|---|
| | | material | | | | | | | | |
| | | powder | | | | | | | | |
| | | WO_{X} | Oxide of additive metal (mol %) | | | | | | | Sintering step |
| | | Value of X | Nb₂O₅ | Ta₂O₅ | T₁O₂ | ZrO₂ | Y₂O₃ | Al₂O₃ | SiO₂ | Method |
| Examples | 1 | 2.62 | — | — | — | — | — | — | — | HP |
| of the | 2 | 2.62 | — | — | — | — | — | — | — | HP |
| present | 3 | 2.62 | — | — | — | — | — | — | — | HP |
| invention | 4 | 2.62 | — | — | — | — | — | — | — | HP |
| | 5 | 2.40 | — | — | — | — | — | — | — | HP |
| | 6 | 2.40 | — | — | — | — | — | — | — | HP |
| | 7 | 2.40 | — | — | — | — | — | — | — | HP |
| | 8 | 2.10 | — | — | — | — | — | — | — | HP |
| | 9 | 2.10 | — | — | — | — | — | — | — | HP |
| | 10 | 2.82 | — | — | — | — | — | — | — | HP |
| | 11 | 2.62 | — | — | — | — | — | — | — | HP |
| | 12 | 2.90 | — | — | — | — | — | — | — | HP |
| | 13 | 2.90 | 10 | — | — | — | — | — | — | HP |
| | 14 | 2.90 | 25 | — | — | — | — | — | — | HP |
| | 15 | 2.72 | 50 | — | — | — | — | — | — | HP |
| | 16 | 2.90 | — | 15 | — | — | — | — | — | HP |
| | 17 | 2.72 | — | — | 20 | — | — | — | — | HP |
| | 18 | 2.90 | — | — | — | 10 | — | — | — | HP |
| | 19 | 2.90 | — | — | — | — | 5 | — | — | HP |
| | 20 | 2.90 | — | — | — | — | — | 15 | — | HP |
| | 21 | 2.90 | — | — | — | — | — | — | 15 | HP |

| | | Sintering step | | | | |
|---|---|---|---|---|---|---|
| | | | Sintering | Pressurizing | Sputtering target | |
| | | Sintering | temperature | pressure | WO_{X} | |
| | | condition | ° C. | MPa | Value of X | M/(W + M) |
| Examples | 1 | A | 1200 | 20 | 2.62 | — |
| of the | 2 | A | 1200 | 35 | 2.62 | — |
| present | 3 | A | 1200 | 10 | 2.62 | — |
| invention | 4 | A | 1200 | 8 | 2.62 | — |
| | 5 | A | 850 | 20 | 2.40 | — |
| | 6 | A | 900 | 20 | 2.40 | — |
| | 7 | A | 1200 | 20 | 2.40 | — |
| | 8 | A | 1200 | 35 | 2.10 | — |
| | 9 | A | 1200 | 10 | 2.10 | — |
| | 10 | A | 1200 | 20 | 2.82 | — |
| | 11 | B | 1200 | 20 | 2.62 | — |
| | 12 | A | 900 | 25 | 2.90 | — |
| | 13 | A | 900 | 25 | 2.89* | 0.18 |
| | 14 | A | 900 | 25 | 2.58* | 0.40 |
| | 15 | A | 900 | 25 | 2.70* | 0.67 |
| | 16 | A | 1200 | 35 | 2.61* | 0.26 |
| | 17 | A | 1100 | 35 | 2.63* | 0.15 |
| | 18 | A | 1100 | 35 | 2.60* | 0.10 |
| | 19 | A | 1100 | 35 | 2.61* | 0.11 |
| | 20 | A | 1100 | 35 | 2.62* | 0.26 |
| | 21 | A | 1100 | 35 | 2.82* | 0.14 |

TABLE 2

| | | Raw | | | | | | | | |
|---|---|---|---|---|---|---|---|---|---|---|
| | | material | | | | | | | | |
| | | powder | | | | | | | | |
| | | WO_{X} | Oxide of additive metal (mol %) | | | | | | | Sintering step |
| | | Value of X | Nb₂O₅ | Ta₂O₅ | T₁O₂ | ZrO₂ | Y₂O₃ | Al₂O₃ | SiO₂ | Method |
| Comparative | 1 | 2.62 | — | — | — | — | — | — | — | HP |
| example | 2 | 2.62 | — | — | — | — | — | — | — | HIP |
| | 3 | 2.62 | — | — | — | — | — | — | — | Atmospheric |
| | | | | | | | | | | firing |
| | 4 | 2.40 | — | — | — | — | — | — | — | HP |
| | 5 | 2.10 | — | — | — | — | — | — | — | HP |
| | 6 | 2.06 | — | — | — | — | — | — | — | HP |
| | 7 | 2.86 | — | — | — | — | — | — | — | HP |
| | 8 | 2.62 | — | — | — | — | — | — | — | HP |
| | 9 | 2.62 | — | — | — | — | — | — | — | HIP |
| | 10 | 2.90 | — | — | 70 | — | — | — | — | HP |

| | | Sintering step | | | | |
|---|---|---|---|---|---|---|
| | | | Sintering | Pressurizing | Sputtering target | |
| | | Sintering | temperature | pressure | WO_{X} | |
| | | condition | ° C. | MPa | Value of X | M/(W + M) |
| Comparative | 1 | C | 1200 | 20 | 2.62 | — |
| example | 2 | — | 1200 | 98 | 2.62 | — |
| | 3 | — | 1200 | — | 3.00 | — |
| | 4 | C | 850 | 20 | 2.40 | — |
| | 5 | C | 1200 | 10 | 2.10 | — |
| | 6 | A | 1200 | 20 | 2.06 | — |
| | 7 | A | 1200 | 20 | 2.86 | — |
| | 8 | D | 1200 | 20 | 2.62 | — |
| | 9 | — | 1200 | 98 | 2.62 | — |
| | 10 | A | 1200 | 25 | 2.90 | 0.71 |

TABLE 3

| | | | Diffraction intensity ratio I_{S(103)}/I_{S(010)} of | | |
|---|---|---|---|---|---|
| | | Area ratio of | W₁₈O₄₉ phase | | |
| | | W₁₈O₄₉ phase | Sputtering surface | Cross section | Density |
| | | % | I_{S(103)}/I_{S(010)} | I_{C(103)}/I_{C(010)} | g/cm³ |
| Examples | 1 | 85 | 2.13 | 0.15 | 8.18 |
| of the | 2 | 84 | 2.56 | 0.13 | 8.19 |
| present | 3 | 86 | 1.34 | 0.35 | 8.02 |
| invention | 4 | 85 | 0.66 | 0.37 | 8.01 |
| | 5 | 56 | 1.46 | 0.31 | 6.85 |
| | 6 | 55 | 1.43 | 0.29 | 7.53 |
| | 7 | 56 | 1.45 | 0.30 | 8.68 |
| | 8 | 38 | 1.20 | 0.28 | 9.02 |
| | 9 | 37 | 0.57 | 0.38 | 8.82 |
| | 10 | 94 | 2.02 | 0.18 | 7.82 |
| | 11 | 85 | 2.01 | 0.20 | 8.17 |
| | 12 | 88 | 0.65 | 0.32 | 6.13 |
| | 13 | 80 | 0.63 | 0.31 | 4.05 |
| | 14 | 58 | 0.68 | 0.35 | 3.52 |
| | 15 | 37 | 0.73 | 0.28 | 3.33 |
| | 16 | 64 | 2.21 | 0.14 | 7.39 |
| | 17 | 89 | 1.12 | 0.24 | 6.74 |
| | 18 | 92 | 1.32 | 0.21 | 7.03 |
| | 19 | 84 | 1.23 | 0.20 | 5.76 |
| | 20 | 74 | 1.18 | 0.24 | 5.57 |
| | 21 | 80 | 1.13 | 0.22 | 5.36 |

| | | Vickers | | | Alkali resistance |
|---|---|---|---|---|---|
| | | hardness of | Crack occurrence output in | | of film after |
| | | sputtering | sputtering test | | atmosphere heat |
| | | surface Hv | Initial stage | Middle stage | treatment |
| Examples | 1 | 943 | None | None | 21 |
| of the | 2 | 960 | None | None | 20 |
| present | 3 | 926 | None | None | 19 |
| invention | 4 | 922 | None | None | 18 |
| | 5 | 765 | 900 W | 900 W | 23 |
| | 6 | 832 | None | None | 22 |
| | 7 | 967 | None | None | 21 |
| | 8 | 915 | None | None | 28 |
| | 9 | 908 | None | None | 27 |
| | 10 | 973 | None | None | 18 |
| | 11 | 937 | None | None | 20 |
| | 12 | 783 | None | None | 18 |
| | 13 | 832 | None | None | 450 |
| | 14 | 888 | None | None | >600 |
| | 15 | 902 | 900 W | 900 W | >600 |
| | 16 | 932 | None | None | >600 |
| | 17 | 892 | None | None | >600 |
| | 18 | 843 | None | None | 63 |
| | 19 | 856 | None | None | 375 |
| | 20 | 827 | None | None | >600 |
| | 21 | 787 | None | None | >600 |

TABLE 4

| | | | Diffraction intensity ratio I_{S(103)}/I_{S(010)} of | | |
|---|---|---|---|---|---|
| | | Area ratio of | W₁₈O₄₉ phase | | |
| | | W₁₈O₄₉ phase | Sputtering surface | Cross section | Density |
| | | % | I_{S(103)}/I_{S(010)} | I_{C(103)}/I_{C(010)} | g/cm³ |
| Comparative | 1 | 86 | 1.32 | 1.30 | 8.19 |
| example | 2 | 85 | 1.68 | 1.63 | 8.20 |
| | 3 | 0 | (No corresponding | (No corresponding | 6.98 |
| | | | peak) | peak) | |
| | 4 | 54 | 0.78 | 0.75 | 6.81 |
| | 5 | 35 | 0.48 | 0.43 | 8.83 |
| | 6 | 28 | 0.88 | 0.36 | 8.99 |
| | 7 | 23 | 2.02 | 0.18 | 7.12 |
| | 8 | 85 | 1.30 | 0.87 | 5.57 |
| | 9 | 85 | 1.61 | 1.62 | 8.17 |
| | 10 | 27 | 1.42 | 0.54 | 4.89 |

| Vickers | | Alkali resistance |
|---|---|---|
| hardness of | Crack occurrence output in | of film after |
| sputtering | sputtering test | atmosphere heat |

| | | surface Hv | Initial stage | Middle stage | treatment |
|---|---|---|---|---|---|
| Comparative | 1 | 904 | 800 W | 600 W | — |
| example | 2 | 903 | 900 W | 700 W | — |
| | 3 | 867 | Unable to perform DC sputtering | | — |
| | | | (no conductivity) | | |
| | 4 | 653 | 600 W | 500 W | — |
| | 5 | 910 | None | 500 W | — |
| | 6 | 990 | Discharge stopped due to great | | — |
| | | | abnormal discharge | | |
| | 7 | 610 | Discharge stopped due to great | | — |
| | | | abnormal discharge | | |
| | 8 | 450 | 400 W | 400 W | — |
| | 9 | 902 | 900 W | 700 W | — |

| | | | |
|---|---|---|---|
| 10 | 463 | Discharge stopped due to great | — |
| | | abnormal discharge | |

In Comparative Example 1, the sintering was performed under the sintering condition C by hot pressing (HP), but the diffraction intensity ratio I_{C(403)}/I_{C(010)} of W₁₈O₄₉ of the cross section orthogonal to the sputtering surface was beyond the range of the present invention. Then, in the sputtering test, cracks were confirmed at 800 W at an initial stage and at 600 W at a middle stage when the sputtering has proceeded.

In Comparative Example 2, the sintering was performed by hot isostatic pressing method (HIP), but the diffraction intensity ratio I_{C(103)}/I_{C(010)} of W₁₈O₄₉ of the cross section orthogonal to the sputtering surface was beyond the range of the present invention. Then, in the sputtering test, cracks were confirmed at 700 W at the middle stage when the sputtering has proceeded.

In Comparative Example 3, as a result of the atmospheric firing, the W₁₈O₄₉ phase was not confirmed, and DC sputtering could not be performed.

In Comparative Example 4, the sintering was performed under the sintering condition C by hot pressing (HP), but the diffraction intensity ratio I_{C(103)}/I_{C(010)} of W₁₈O₄₉ of the cross section orthogonal to the sputtering surface was beyond the range of the present invention. Then, in the sputtering test, cracks were confirmed at 600 W at an initial stage and at 500 W at a middle stage when the sputtering has proceeded.

In Comparative Example 5, the sintering was performed under the sintering condition C by hot pressing (HP), but the diffraction intensity ratio I_{S(103)}/I_{S(010)} of W₁₈O₄₉ of the sputtering surface and the diffraction intensity ratio I_{C(103)}/I_{C(010)} of W₁₈O₄₉ of the cross section orthogonal to the sputtering surface were beyond the range of the present invention. Then, in the sputtering test, cracks were confirmed at 900 W at an initial stage and cracks were confirmed at 500 W at a middle stage when the sputtering has proceeded.

In Comparative Example 6, WO_{X} (X=2.06) was obtained, the area ratio of the W₁₈O₄₉ phase was low as 28%, and abnormal discharge occurred frequently during DC sputtering and the discharge was stopped. Accordingly, the sputtering could not be performed. It is surmised that it is because there was a large amount of WO₂ phase.

In Comparative Example 7, WO_{X} (X=2.86) was obtained, the area ratio of the W₁₈O₄₉ phase was low as 23%, and abnormal discharge occurred frequently during DC sputtering and the discharge was stopped. Accordingly, the sputtering could not be performed. It is surmised that it is because there was a large amount of WO₃ phase.

In Comparative Example 8, the sintering was performed under the sintering condition D by hot pressing (HP), but the density was low and sufficient sintering could not be performed. In addition, the diffraction intensity ratio I_{C(103)}/I_{C(010)} of W₁₈O₄₉ of the cross section orthogonal to the sputtering surface was beyond the range of the present invention. Then, in the sputtering test, cracks were confirmed at 400 W at an initial stage and at 400 W at a middle stage when the sputtering has proceeded.

In Comparative Example 9, the sintering was performed by hot isostatic pressing method (HIP), but the diffraction intensity ratio I_{C(103)}/I_{C(010)} of W₁₈O₄₉ of the cross section orthogonal to the sputtering surface was beyond the range of the present invention. Then, in the sputtering test, cracks were confirmed at 700 W at the middle stage when the sputtering has proceeded.

In Comparative Example 10, 70 mol % of TiO₂ was contained, the area ratio of the W₁₈O₄₉ phase of the surface parallel to the sputtering surface was low as 27%, and abnormal discharge occurred frequently during DC sputtering and the discharge was stopped. Accordingly, the sputtering could not be performed.

In contrast, in Examples 1 to 10 and 12 of the present invention, as a result of the sintering performed under the sintering condition A by hot pressing (HP), the diffraction intensity ratio I_{S(103)}/I_{S(010)} of W₁₈O₄₉ of the sputtering surface and the diffraction intensity ratio I_{C(103)}/I_{C(010)} of W₁₈O₄₉ of the cross section orthogonal to the sputtering surface were in the ranges of the present invention, and the area ratio of the W₁₈O₄₉ phase was also in the range of the present invention. In Examples 1 to 4 and 6 to 12 of the present invention, no crack was confirmed, even in a case where the output was increased to 1000 W at both the initial and middle stages of the sputtering test. In addition, in Example 5 of the present invention, the crack was confirmed at 900 W at both the initial and middle stages of the sputtering test, but it was sufficiently usable.

In addition, in Example 11 of the present invention, as a result of the sintering performed under the sintering condition B by hot pressing (HP), the diffraction intensity ratio I_{S(103)}/I_{S(010)} of W₁₈O₄₉ of the sputtering surface and the diffraction intensity ratio I_{C(103)}/I_{C(010)} of W₁₈O₄₉ of the cross section orthogonal to the sputtering surface were in the range of the present invention and the area ratio of the W₁₈O₄₉ phase was also in the range of the present invention. No crack was confirmed, even in a case where the output was increased to 1000 W at both the initial and middle stages of the sputtering test.

In addition, in Examples 13 to 21 of the present invention, the oxide of the additive metal was added, but the diffraction intensity ratio I_{S(103)}/I_{S(010)} of W₁₈O₄₉ of the sputtering surface and the diffraction intensity ratio I_{C(103)}/I_{C(010)} of W₁₈O₄₉ of the cross section orthogonal to the sputtering surface were in the range of the present invention and the area ratio of the W₁₈O₄₉ phase was also in the range of the present invention. In Examples 13, 14, and 16 to 21 of the present invention, no crack was confirmed, even in a case where the output was increased to 1000 W at both the initial and middle stages of the sputtering test. in addition, in Example 15 of the present invention, the crack was confirmed at 900 W at both the initial and middle stages of the sputtering test, but it was sufficiently usable.

The alkali resistance was greatly improved, compared to Examples 1 to 12 of the present invention in which the oxide of the additive metal was not added.

As described above, according to the examples of the present invention, it was confirmed that it is possible to provide a tungsten oxide sputtering target capable of suppressing occurrence of cracks and stably performing sputtering film formation, although the sputtering is performed under high power conditions.

### INDUSTRIAL APPLICABILITY

According to the present invention, it is possible to provide a tungsten oxide sputtering target capable of suppressing occurrence of cracks and stably performing sputtering film formation for a long period of time, although the sputtering is performed under high power conditions.

1. A tungsten oxide sputtering target,
wherein a W₁₈O₄₉ peak is confirmed by X-ray diffraction analysis of a sputtering surface and a cross section orthogonal to the sputtering surface,
a ratio I_{S(103)}/I_{S(010)} of a diffraction intensity I_{S(103)} of a (103) plane to a diffraction intensity I_{S(010)} of a (010) plane of W₁₈O₄₉ of the sputtering surface is 0.57 or more,
a ratio I_{C(103)}/I_{C(010)} of a diffraction intensity I_{C(103)} of the (103) plane to a diffraction intensity I_{C(010)} of the (010) plane of W₁₈O₄₉ of the cross section is 0.38 or less, and
an area ratio of a W₁₈O₄₉ phase of a surface parallel to the sputtering surface is 37% or more.

2. The tungsten oxide sputtering target according to claim 1 having a composition of WO_{X} (2.1≤X≤2.9).

3. The tungsten oxide sputtering target according to claim 1, comprising:
an oxide of any one or two or more additive metals of Nb, Ta, Ti, Zr, Y, Al and Si, wherein, as a metal component, in a case where a total amount of the additive metal is defined as M (atom %) and an amount of tungsten is defined as W (atom %), M/(W+M) is in a range of 0.1 or more and 0.67 or less.

4. The tungsten oxide sputtering target according to claim 2, comprising:
an oxide of any one or two or more additive metals of Nb, Ta, Ti, Zr, Y, Al and Si, wherein, as a metal component, in a case where a total amount of the additive metal is defined as M (atom %) and an amount of tungsten is defined as W (atom %), M/(W+M) is in a range of 0.1 or more and 0.67 or less.
